(19) United States
(12) Patent Application Publication
(10) Pub. No.: US 2026/0215334 A1
(43) Pub. Date: Jul. 23, 2026

(54) MULTISTAGE SEALED POWER-ELECTRONIC MODULE

(71) Applicant: SAFRAN ELECTRONICS & DEFENSE, PARIS (FR)

(72) Inventors: Jean-Christophe RIOU, MOISSY CRAMAYEL (FR); Nawres SRIDI-CONVERS, MOISSY CRAMAYEL (FR)

(21) Appl. No.: 19/140,810

(22) PCT Filed: Dec. 19, 2023
(86) PCT No.: PCT/FR2023/052065

§ 371 Date: Jul. 3, 2025

(30) Foreign Application Priority Data
Dec. 22, 2022 (FR) FR2214333

(51) Int. Cl. H10W 76/63; H10D 80/20; H10W 40/20; H10W 40/25; H10W 70/20; H10W 70/60; H10W 72/00; H10W 76/13; H10W 76/15; H10W 76/18; H10W 90/00; H10W 90/10; H10W 90/20; H10W 90/22

(52) U.S. Cl. CPC H10W 76/63; H10W 40/233; H10W 40/258; H10W 70/24; H10W 70/611; H10W 72/07332; H10W 76/13; H10W 76/15; H10W 76/18; H10W 90/10; H10W 90/22; H10W 90/291; H10W 90/401; H10D 80/231; H10D 80/251; H10W 90/734; H10W 90/736

(57) ABSTRACT

A power-electronic module includes a substrate; a first power-electronic component arranged on a first face of the substrate; a first cover which defines, together with the substrate, a first cavity in which the first power-electronic component is housed; a second power-electronic component arranged on a second face of the substrate; and a second cover which defines, together with the substrate, a second cavity in which the second power-electronic component is housed; a first ring seal which seals the first cavity; a second ring seal which seals the second cavity; wherein the first and second ring seals are formed from a sintered material and wherein the first and second cavities hold a gas or a mixture of gases.

### TECHNICAL FIELD OF THE INVENTION

The technical field of the invention is that of electronic power modules.

This invention more particularly relates to an electronic power module comprising several electronic power components distributed over several levels or stages.

### TECHNOLOGICAL BACKGROUND OF THE INVENTION

Electronic power modules enable the implementation of basic functions such as switching, rectification, voltage division, etc.

A so-called “2D” or “single-stage” power module generally comprises one or more electronic power components brazed onto a ceramic substrate provided with metal tracks. The ceramic substrate is attached to a copper baseplate, which serves as mechanical support and transfers heat generated by the components to a cooling device, typically a heat dissipator. Electrical connections inside the power module, between the components and the metal tracks of the substrate, are provided in part by so-called bonding wires. The components are enclosed in a case filled with an encapsulation material.

The purpose of the encapsulation material is to ensure dielectric strength of the power module and to protect the components from external aggression (moisture, contamination, etc.). In addition, it enhances electrical insulation between conductors and improves resistance to partial discharges due especially to defects in metallisations of the ceramic substrate.

Electronic power components can be transistors, thyristors and diodes. These components are formed of a semiconductor material. Wide bandgap (or wide gap) semiconductor materials, such as gallium nitride (GaN), gallium arsenide (GaAs), silicon carbide (SIC) and diamond, are tending to replace silicon, due to their better performance in terms of current density, operating frequency and resistance to voltages.

There are also so-called “3D” or “multi-stage” electronic power modules, comprising several electronic components distributed over different levels (also referred to as “stages”). Electronic components are typically disposed on either side of a substrate, or between several stacked substrates.

The operation of an electronic power module (single or multi-stage) generates temperature cycles that can be relatively severe. These temperature cycles produce significant mechanical stresses in the substrate(s) and at the interfaces between the electronic components and the substrate(s). These mechanical stresses originate multiple failure modes in the electrical power module.

Document WO2019/101634A1 describes a multi-stage electronic power module designed to reduce the risk of failure. This electronic power module has metal supports and electronic power components disposed on or between the metal supports. The metal supports are assembled to each other so that the electronic power module has a generally tubular external shape of circular cross-section. The supports are T-shaped, F-shaped or right-angled in cross-section.

Metal supports, through which power electric currents flow to and from electronic components, enable heat to be dissipated efficiently by conduction, convection and radiation simultaneously. Metal supports provide a substrate free of ceramic layers likely to be embrittled by thermal cycles.

The electrical power module further comprises a sealed, tubular cap manufactured from plastic. This cap is attached to part of the metal supports. The metal supports and the cap together define an internal channel, in which a cooling fluid circulates, for example a gas or a heat-transfer liquid. Circulation of the cooling fluid in the internal channel enables the module to be cooled. The cooling fluid further ensures electrical insulation of the module.

However, the electronic power module described in document WO2019/101634A1 is difficult to integrate into an electromechanical actuator, such as an electric motor, because of the cooling fluid circulation.

### SUMMARY OF THE INVENTION

There is therefore a need for a multi-stage electronic power module with good electrical insulation performance that is easy to integrate.

According to one aspect of the invention, this need tends to be met by providing an electronic power module comprising:
a substrate having a first face and a second face opposite to the first face;
a first electronic power component disposed on the first face of the substrate;
a first cap disposed on the first face of the substrate and delimiting together with the substrate a first cavity in which the first electronic power component is housed;
a second electronic power component disposed on the second face of the substrate;
a second cap disposed on the second face of the substrate and delimiting together with the substrate a second cavity in which the second electronic power component is housed.
a first annular seal disposed between the substrate and the first cap, the first annular seal sealingly closing the first cavity; and
a second annular seal disposed between the substrate and the second cap, the second annular seal sealingly closing the second cavity.

The first and second annular seals are formed of a sintered material, preferably silver-based, and the first and second cavities enclose a gas or gas mixture.

The gas (or gas mixture) contained in the first and second sealed cavities provides a high degree of electrical insulation between internal elements of the electronic power module. The power module is thus free of encapsulation material (generally a polymer material), which tends to degrade over the course of partial discharges in the 2D module of prior art (especially in the so-called triple point zone, between the ceramic substrate, the metal track carrying the electric current and the encapsulation material).

The integration of the electronic power module, for example in an electromechanical actuator, is further facilitated by the fact that no fluid circulation is required. On the contrary, the electrical insulating gas is enclosed herein. Additionally, sintering is a technique for easily forming annular seals that seal the caps to the substrate and close the cavities.

In a first embodiment of the electronic power module, the first cap comprises:
a first substrate formed of a first electrically insulating ceramic material; and
at least one first conductive element passing through the first substrate and electrically connected to the first electronic power component; and the second cap comprises:
a second substrate formed of a second electrically insulating ceramic material; and
at least one second conductive element passing through the second substrate and electrically connected to the second electronic power component.

According to one development of this first embodiment, the first and second substrates are of aluminium nitride.

In a second embodiment, the first and second caps each comprise a metal layer and an electrically insulating layer disposed on an external face of the metal layer.

The electronic power module may further comprise:
a third electronic power component disposed on the first face of the substrate and housed in the first cavity; and
a fourth electronic power component disposed on the second face of the substrate and housed in the second cavity.

For example, the first electronic power component is connected in parallel with the third electronic power component, the second electronic power component is connected in parallel with the fourth electronic power component, the first electronic power component is a transistor, the second electronic power component is a transistor, the third electronic power component is a diode and the fourth electronic power component is a diode.

Further to the characteristics discussed in the preceding paragraphs, the electronic power module according to the first aspect of the invention may have one or more additional characteristics from among the following, considered individually or according to any technically possible combinations:
the substrate is of metal;
the first electronic power component comprises a first terminal electrically connected to the substrate and a second terminal electrically connected to a conductive portion of the first cap;
the second electronic power component comprises a first terminal electrically connected to the substrate and a second terminal electrically connected to a conductive portion of the second cap;
each of the first and second electronic power components is electrically connected to the substrate via a conductive track and a conductive seal formed of the sintered material;
the first electronic power component is electrically connected to the conductive portion of the first cap via a conductive track and a conductive seal formed of the sintered material; and
the second electronic power component is electrically connected to the conductive portion of the second cap via a conductive track and a conductive seal formed of the sintered material.

A second aspect of the invention relates to an electromechanical actuator comprising at least one electronic power module according to the first aspect of the invention.

The electromechanical actuator preferably comprises a three-phase motor and a three-phase motor drive and supply circuit, the three-phase motor drive and supply circuit comprising a plurality of electronic power modules according to the first aspect of the invention for generating phase currents for the three-phase motor.

Each electronic power module is advantageously disposed facing a winding overhang of the three-phase motor.

A third aspect of the invention relates to a method for manufacturing an electronic power module, comprising the following steps of:
providing a substrate, a first cap and a second cap;
attaching a first electronic power component to the first cap;
depositing a sintering material onto the first cap so as to form a first bead around the first electronic power component;
attaching a second electronic power component to the second cap;
depositing the sintering material onto the second cap so as to form a second bead around the second electronic power component;
transferring the first cap to a first face of the substrate and the second cap to a second opposite face of the substrate, by disposing the first and second beads of sintering material in contact with the substrate; and
sintering the sintering material to form first and second annular seals, the first annular seal delimiting and sealingly closing a first cavity delimited by the first cap and the substrate and the second annular seal delimiting and sealingly closing a second cavity delimited by the second cap and the substrate, the first and second cavities enclosing a gas or gas mixture.

Preferably, the substrate is of aluminium and the method further comprises, prior to the step of transferring the caps, a step of forming silver-based conductive tracks on the first face and the second face of the substrate, the step of forming the silver-based conductive tracks comprising the following operations:
depositing by screen printing a paste comprising silver particles;
drying paste; and
annealing the paste at a temperature equal to or greater than 570° C.

### BRIEF DESCRIPTION OF THE FIGURES

Further characteristics and advantages of the invention will become apparent from the description thereof given below, by way of indicating and in no way limiting purposes, with reference to the appended figures, in which:

FIG. 1 is a schematic cross-section view of an electronic power module according to a first embodiment;

FIG. 2 is a schematic cross-section view of an electronic power module according to a second embodiment;

FIG. 3 is a perspective partial view of a three-phase motor into which several electronic power modules are integrated; and

FIGS. 4A to 4E schematically represent steps in a method for manufacturing the electronic power module; and

FIG. 5 represents an aluminium-silver phase diagram.

For greater clarity, identical or similar elements are identified by identical reference signs throughout the figures.

### DETAILED DESCRIPTION

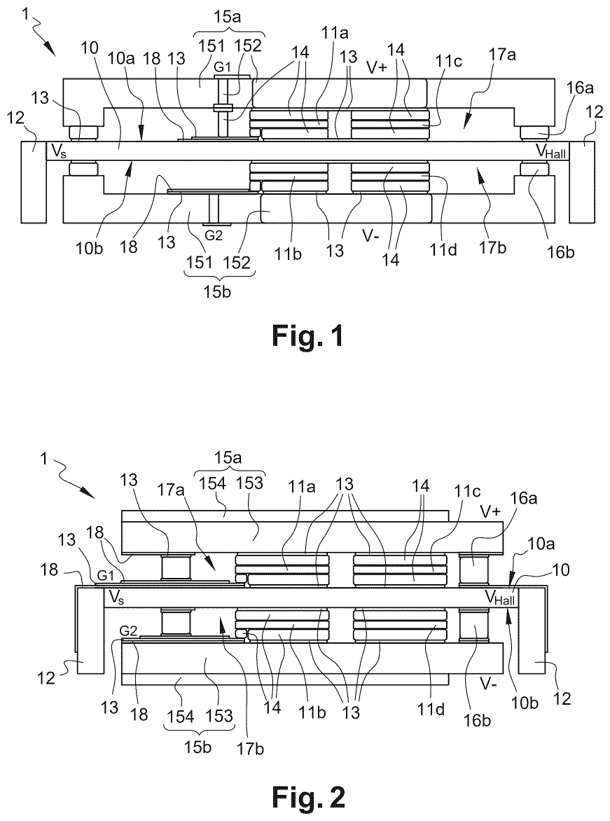

FIG. 1 schematically represents an electronic power module 1 according to a first embodiment. The electronic power module 1 can have the function of converting an AC voltage into a DC voltage (function of a rectifier), converting a DC voltage into an AC voltage (inverter), modifying the RMS value of an AC voltage (dimmer), modifying the mean value of a DC voltage (chopper) or modifying the frequency of an AC voltage (cycloconverter) or dissipating a current (active resistor).

The power module 1 comprises a substrate 10 and at least two electronic power components: a first component 11a disposed on a first face 10a of the substrate 10 and a second component 11b disposed on a second face 10b of the substrate 10, opposite to the first face 10a.

As such, the power module 1 comprises two component stages, a first stage comprising (at least) the first component 11a and a second stage comprising (at least) the second component 11b.

The substrate 10 is preferably metallic. It can be formed of a single metal layer, for example of aluminium or copper, or from several stacked metal layers formed of different metals. It is of the shape of a rectangular plate, for example. Its thickness is preferably between 0.2 mm and 2 mm. It can have recesses, bosses (preferably with a width to height ratio between 1 and 3) and extra thicknesses, in other words it can be textured. Thus, its faces 10a-10b are not necessarily planar, as is schematically represented in FIG. 1. They may furthermore be rough and/or porous.

Advantageously, the substrate 10 forms a power conductor which carries one or more electrical outputs of the power module 1. It is capable of conducting a high electric current, typically greater than 20 A.

One or more additional conductors 12 may be attached to the substrate 10, in order to facilitate connection of the power module 1 to one or more electrical devices (an electric motor and a current sensor in the example hereinafter). For example, the power module 1 of FIG. 1 comprises two additional conductors 12 attached to two opposite faces of the substrate 10. These additional conductors 12 then constitute output terminals of the power module 1. Each additional conductor 12 preferably extends perpendicularly to the substrate 10.

The substrate 10 thus serves as an electrical bridge (or common point) between the two component stages. During operation of the power module 1, the temperature at the substrate 10 is substantially constant due to the fact that it is entirely metallic. Abrupt variations in temperature, referred to as transients, are eliminated, which has the effect of decreasing (thermal) noise on the electrical output(s) of the power module 1 and improving reliability from the point of view of thermomechanical stresses.

The substrate 10 is advantageously covered, on each of its faces 10a-10b, with one or more electrically conductive tracks 13 referred to as finishes. These conductive tracks 13 preferably consist of a silver-based conductive material, which has the advantage of being inoxidisable.

The first and second components 11a-11b are each electrically connected to the substrate 10, preferably via one of the conductive tracks 13 and a conductive seal 14 formed of sintered material. The conductive seal 14 is disposed on the conductive track 13.

The sintered material of the conductive seals 14 is advantageously silver-or copper-based. In particular, a silver-based conductive seal 14 and a conductive track 13 based on the same metal form a high-performance electrical and mechanical connection, especially in terms of resistance and electrical and thermal conductivity. This type of connection especially supports the high operating temperatures common in electronic power modules.

Alternatively, the silver-or copper-based conductive seals 14 are formed on conductive tracks or finishes of the ENIG (“Electroless Nickel Immersion Gold”) or ENEPIG (“Electroless Nickel Electroless Palladium Immersion Gold”) type.

The power module 1 further comprises:
a first cap 15a disposed on the first face 10a of the substrate 10;
a second cap 15b disposed on the second face of the substrate 10;
a first annular seal 16a disposed between the substrate 10 and the first cap 15a; and
a second annular seal 16b disposed between the substrate 10 and the second cap 15b.

The first cap 15a delimits together with the substrate 10 a first cavity 17a in which the first component 11a is housed, while the second cap 15b delimits together with the substrate 10 a second cavity 17b in which the second component 11b is housed.

Preferably, the first component 11a is electrically connected to the first cap 15a, and the second component 11b is electrically connected to the second cap 15b. The components 11a-11b are advantageously connected to the caps 15a-15b in the same way as to the substrate 10, via conductive tracks 13 (herein disposed on the internal faces of the caps 15a-15b) and conductive seals 14.

The first annular seal 16a and the second annular seal 16b sealingly close the first cavity 17a and the second cavity 17b respectively. They are formed of a sintered material, preferably silver-based. This sintered material is advantageously the same as that of the conductive seals 14. Using the same sintered material to form the conductive seals 14 and the annular seals 16a-16b greatly simplifies manufacture of the power module 1.

In order to reduce the risk of the caps 15a-15b becoming detached, each annular seal 16a, 16b is advantageously disposed in contact with a conductive track 13 disposed on the substrate 10.

The substrate 10 extends beyond the annular seals 16a-16b to make the electrical connection of the power module 1 possible (directly or via the additional conductors 12).

The cavities 17a-17b enclose a gas, preferably a neutral gas such as argon, nitrogen or helium. Alternatively, they may contain a gas mixture, for example air. The pressure of the gas (or gas mixture) may be atmospheric pressure (at the time the cavities 17a-17b are sealed) or a much lower pressure, typically less than 133.3×10⁻³ Pa (i.e. 10⁻³ Torr), so as to obtain a primary vacuum configuration. The gas pressure is advantageously between 133.3×10⁻⁶ Pa (10⁻⁶ Torr) and 133.3×10⁻⁷ Pa (10⁻⁷ Torr), i.e. a secondary vacuum configuration, to avoid partial discharges that can occur in a primary vacuum. Cavities 17a-17b contain no water vapour.

The gas contained in the cavities 17a-17b provides electrical insulation between the internal elements of the power module 1. The annular seals 16a-16b especially prevent moisture from entering the cavities 17a-17b, which could cause partial discharges. This helps to increase reliability and electrical connections of the components. Furthermore, electrical insulation of the electronic power module 1 is independent of cooling and does not require circulating a fluid as in the module of prior art, which facilitates its integration.

The annular seals 16a-16b enable a case-junction thermal resistance RJc of less than 0.3° C./W to be obtained. They also make it possible to obtain a more compact module than those of prior art with an encapsulation (or coating) material.

Just like the substrate 10, the caps 15a-15b preferably have a generally parallelepiped shape. Each of the caps 15a-15b advantageously has a thickness between 0.2 mm and 2 mm. The power module 1 is therefore of low overall size, unlike the power module of prior art, whose metal supports have right angles.

The thickness of the caps 15a-15b may be constant or substantially constant (variation in thickness of less than 100 μm). One or both of the caps 15a-15b may alternatively have a peripheral rim, which extends towards the substrate 10, in order to increase the volume of the first cavity 17a and/or the second cavity 17b (especially according to the thickness of the components they contain).

Preferably, the caps 15a and 15b are manufactured using the same material(s) and have the same dimensions, making the power module 1 overall symmetrical relative to the substrate 10. This symmetry reduces mechanical stresses within the power module 1, especially bending stresses (by locating the neutral plane of the module in the substrate 10).

The first and second components 11a-11b are preferably active components, for example of the transistor, diode or thyristor type. They comprise at least two terminals or electrodes (not represented in the figure). Advantageously, the first terminals of the first and second components 11a-11b are electrically connected to the substrate 10, the second terminal of the first component 11a is electrically connected to a conductive portion of the first cap 15a, and the second terminal of the second component 11b is electrically connected to a conductive portion of the second cap 15b. Thus, the caps are functionalised in that they serve to transmit electrical signals between outside and inside of the power module 1.

The electrical connection of the electronic power module 1 is advantageously made on the external faces of the caps 15a-15b and at least one of the ends of the central substrate 10, which further facilitates its integration, especially in electrical devices where the available space is restricted. The external faces of the caps 15a-15b are preferably planar or substantially planar (variation in thickness less than 100 μm).

In this first embodiment, the caps 15a-15b each comprise a substrate 151 of an electrically insulating ceramic material and one or more electrically conductive elements 152 passing through the substrate 151. The conductive elements 152, also referred to as inserts, are hermetic, i.e. they prevent any exchange of fluid (such as water vapour) between outside and inside of the power module 1. They serve to conduct electric currents between outside and inside of the module, to or from the electronic power components.

Thus, at least one conductive element 152 of the first cap 15a is electrically connected to the second terminal of the first component 11a and at least one conductive element 152 of the second cap 15b is electrically connected to the second terminal of the second component 11b. The components 11a-11b are advantageously connected to the conductive elements 152 of the caps 15a-15b in the same way as to the substrate 10, via conductive tracks 13 (herein disposed on the internal faces of the caps 15a-15b) and conductive seals 14.

Conductive elements 152 can also serve to dissipate heat generated by components 11a-11b (electrically and thermally conductive elements).

The conductive elements 152 can especially be via or heat dissipators. They are preferably formed of one or more metals, for example selected from copper, aluminium, tungsten, gold, titanium, silver, palladium and alloys thereof.

The substrates 151 of the caps 15a-15b are preferably formed of the same ceramic material, for example aluminium nitride (AlN), aluminium oxide (Al₂O₃), silicon carbide (SIC), aluminium-silicon carbide (AISiC) or silicon nitride (Si₃N₄). Aluminium nitride is particularly advantageous, as it has high thermal conductivity, high electrical resistivity and can easily incorporate hermetic inserts. Compared with metals, it furthermore has a coefficient of thermal expansion closer to that of the semiconductor materials forming the base of components 11a-11b. Caps 15a-15b comprising aluminium nitride, therefore have the advantage of considerably reducing thermomechanical stresses within the power module 1.

As is represented by FIG. 1, the power module 1 can comprise more than two electronic power components, for example two per stage, making a total of four.

The power module 1 may therefore comprise:
a third component 11c disposed on the first face 10a of the substrate 10 and housed in the first cavity 17a;
a fourth component 11d disposed on the second face 10b of the substrate 10 and housed in the second cavity 17b.

Just like the first and second components 11a-11b, each of the third and fourth components 11c-11d is connected to the substrate 10 and to at least one conductive element 152 of the caps 15a-15b, preferably via a conductive track 13 and a conductive seal 14 made of sintered material.

The electronic power module 1 can be (easily) integrated into an electromechanical actuator. By way of example, the electromechanical actuator comprises a three-phase motor and a power supply and control circuit for the three-phase motor. This electrical circuit comprises a plurality of power modules 1, preferably as many power modules 1 as the three-phase motor comprises inductors or coils. Each power module 1 serves to supply the motor by generating one of the phase currents of the motor.

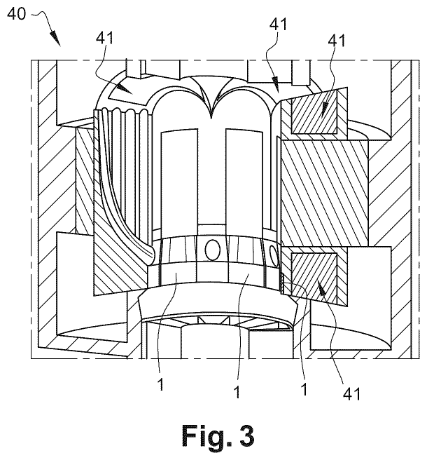

FIG. 3 represents part of the three-phase motor 40. Only three coils are represented and the motor shaft has been deliberately omitted. The power modules 1 are advantageously disposed inside the motor 40, preferably opposite the winding overhangs 41 of the motor 40 (one module per coil).

In this application example, the power module 1 is in a four-component configuration. Components 11a-11d are connected together to form a bridge arm of an inverter mounting. The first component 11a is a transistor (preferably a Metal Oxide Semiconductor Field Effect Transistor (MOSFET) or Insulated Gate Bipolar Transistor (IGBT)), the second component 11b is a transistor (preferably a MOSFET or IGBT), the third component 11c is a diode and the fourth component 11d is a diode.

Again with reference to FIG. 1, the first component 11a (transistor) and the third component 11c (diode) are connected in parallel, between a positive supply voltage V+, carried by a conductive element 152 of the first cap 15a (for example a heat dissipator of copper-tungsten alloy), and a first electrical output Vs of the power module 1, carried by the substrate 10. The second component 11b (transistor) and the fourth component 11d (diode) are connected in parallel, between a negative supply voltage V−, carried by a conductive element 152 of the second cap 15b (for example a heat dissipator of copper-tungsten alloy), and the electrical output Vs of the power module 1.

A first control signal G1 is routed to the gate electrode of transistor 11a, herein through a via 152 (for example of tungsten) passing through the first cap 15a, a conductive seal 14 of sintered material and a conductive track 13 disposed on the first face 10a of the substrate 10 but electrically insulated therefrom by a first dielectric layer 18.

Similarly, a second control signal G2 is routed to the gate electrode of transistor 11b, herein through a via 152 (for example of tungsten) passing through the second cap 15b and a conductive track 13 disposed on the internal face of the second cap 15b (possibly covered with a second dielectric layer 18 to enhance electrical insulation).

The power module 1 comprises a second electrical output VHall, carried by the substrate 10 and connected to a current sensor, for example with Hall effect. This current sensor measures the phase current delivered to the motor. In this example, the power module 1 is thus a bridge arm of an inverter incorporating a current measurement.

FIG. 2 represents an electronic power module 1 according to a second embodiment. This second embodiment differs from the first embodiment essentially in the constitution of the caps 15-15b. Herein, the caps 15-15b each comprise a metal layer 153 rather than a ceramic substrate. Advantageously, they further comprise an electrically insulating layer 154 disposed on the external face of the metal layer 153. The insulating layers 154 limit partial discharges between the metal layers 153 of the caps 15a-15b and neighbouring conductive parts, for example those of the motor into which the power module 1 is integrated. They are of AlN, for example, and have a thickness of 100 μm.

The metal layer 153 of the first cap 15a and the metal layer 153 of the second cap 15b carry the positive supply voltage V+ and the negative supply voltage V− respectively. The insulating layer 154 completely covers the external face of the metal layer 153, with the exception of a portion required for making electrical contact. The control signal G1 of the transistor 11a is herein routed by a conductive track 13 disposed on substrate 10 and separated from the substrate 10 by a first dielectric layer 18. The control signal G2 of the transistor 11b is herein routed by a conductive track 13 deposited onto the internal face of the second cap 15b and separated from the metal layer 153 of this same cap by a second dielectric layer 18.

To prevent short circuits between the (metal) substrate 10 and the caps 15a-15b, the annular seals 16a-16b are separated from the substrate 10 and the caps 15a-15b by further dielectric layers 18.

The metal layers 153, the substrate 10 and the annular seals 16a-16b thus form a structure similar to a Faraday cage, which protects the electronic components from electromagnetic fields and electrostatic discharges.

The power module 1 is not limited to the embodiments described in connection with FIGS. 1 and 2. In particular, each stage of components may include several (two or more) electronic power components (preferably of the transistor, diode or thyristor type) connected in parallel or in series.

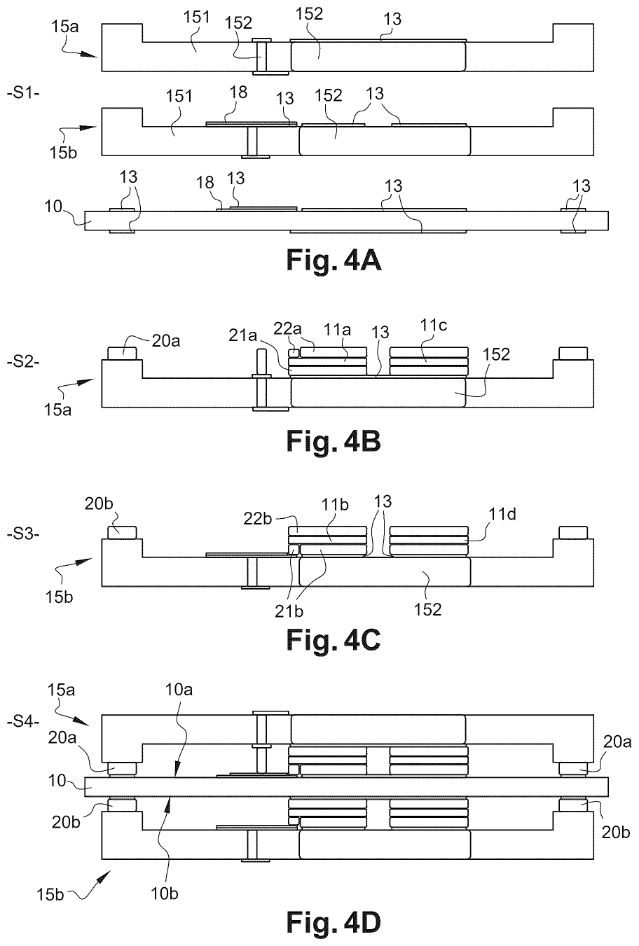

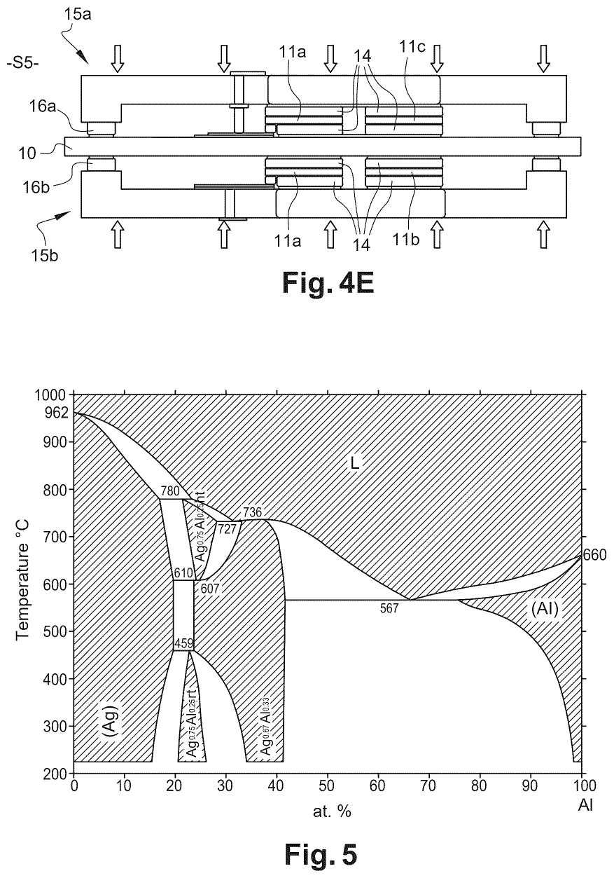

FIGS. 4A to 4E schematically represent steps S1 to S5 of a method for manufacturing the power module 1.

The first step S1 in this manufacturing method, illustrated in FIG. 4A, consists in providing the substrate 10 and the caps 15a-15b, in preparation for transferring the electronic power components (steps S2 and S3; FIGS. 4B-4C) and assembling them by sintering (steps S4 and S5; FIGS. 4D-4E).

The manufacturing method may further comprise forming one or more conductive tracks 13 on each of the faces 10a-10b of the substrate 10 and depositing one or more dielectric layers 18 on either or both of the faces 10a-10b.

Providing the first cap 15a or the second cap 15b may comprise, in the case of the power module 1 according to the first embodiment (cf. FIGS. 1 & 4A), the following operations:
providing a ceramic substrate 151; and
forming one or more conductive elements 152 (or inserts) in the ceramic substrate 151, for example by creating cavities and filling them with metal.

The manufacturing method may then comprise forming one or more conductive tracks 13 on the internal face of the cap 15a, 15b, and depositing one or more dielectric layers 18 onto this same internal face.

The conductive tracks 13 are formed, for example, by screen printing, drying and annealing a silver paste, such as that marketed by the company Dupont™ under the reference AS300. The dielectric layers 18 can also be formed in this way, using a dielectric paste such as that marketed by Dupont™ under the reference AS100.

The silver paste, sometimes referred to as “ink”, comprises silver particles dispersed in a matrix comprising preferably a metal oxide, for example aluminium oxide (Al₂O₃).

By default, holding silver conductive tracks 13 on a substrate 10 or a metal layer 153 (caps 15a-15b) of aluminium is poor, due to the presence on the surface of a layer of native oxide (Al₂O₃) which forms a barrier layer. To remedy this, it is possible to dissolve this native oxide layer (and therefore deoxidise the surface) before depositing the silver paste, for example by depositing a zincate thereon.

In a preferred mode of implementation of the manufacturing method, the annealing of the silver paste is performed at a temperature of 570° C. or above (rather than 450° C. as recommended by the manufacturer for AS 300 paste). The phase diagram of FIG. 5 shows that at 567° C. and above, the annealing forms an aluminium-silver eutectic alloy, rather than an intermetallic alloy (between 425° C. and 567° C.). But it is estimated that the strength of the eutectic alloy is four times greater than that of the intermetallic alloy, while being more stable over time, at least in terms of tear strength. Furthermore, annealing at such a temperature breaks the aluminium oxide barrier layer. It is therefore not necessary to carry out a deoxidation step beforehand. The annealing time is preferably between 30 min and 300 min.

Step S2 of FIG. 4B comprises:
attaching the first component 11a to the internal face of the first cap 15a, and more particularly to a conductive track 13;
depositing a first sintering material onto the first cap 15a so as to form a first annular bead (or strip) 20a around the first component 11a or its location; and
drying the first sintering material, for example for 40 min at 150° C.

Although represented in the same figure, these operations are performed successively (attaching the first component 11a can be achieved before or after forming the first annular bead 20a).

As represented in FIG. 4B, the first annular bead 20a may be formed on a peripheral rim of the first cap 15a.

Attaching the first component 11a preferably comprises forming a first layer 21a of a second sintering material on the first cap 15a, depositing the first component 11a onto the first layer 21a and drying the second sintering material of the first layer 21a. The first component 11a will thus be connected to the first cap 15a by a seal of sintered material rather than by welding or soldering.

Step S2 may also comprise forming a second layer 22a made of the second sintering material on the first component 11a, to subsequently connect the first component 11a to the substrate 10 by a seal of sintered material. Alternatively, the second layer 22a of second sintering material is deposited onto the substrate 10.

Sintering materials are in the form of a paste comprising metal particles, preferably silver, and one or more organic elements whose purpose is to give cohesion to the paste and enable it to be applied by screen printing (binder) and/or to separate the particles and prevent them from sintering before they are intended to (dispersant). These organic elements are largely removed during the drying operation. The sintering paste may also include additives to accelerate (subsequent) sintering of the particles.

Possible other electronic power components belonging to the same stage of components, such as the third component 11c, are preferably attached to the first cap 15a in the same way as the first component 11a.

Likewise, step S3 of FIG. 4C comprises attaching the second component 11b to the internal face of the second cap 15b (and more particularly to a conductive track 13), depositing the first sintering material on the second cap 15b so as to form a second annular bead 20b around the second component 11b (or its location) and drying the first sintering material. The second annular bead 20b is formed, for example, on a peripheral rim of the second cap 15b.

Attaching the second component 11b preferably comprises forming a third layer 21b of the second sintering material on the second cap 15b, depositing the second component 11b onto the third layer 21b and drying the second sintering material of the third layer 21b.

Step S3 may also comprise forming a fourth layer 22b of second sintering material on the second component 11b, to subsequently connect the second component 11b to the substrate 10 by a seal of sintered material. Alternatively, the fourth layer 22b of second sintering material is deposited onto the substrate 10.

Possible other electronic power components belonging to the same stage of components, such as the fourth component 11d, are preferably attached to the second cap 15b in the same way as the second component 11a.

Before depositing the sintering materials, an Ar/H₂ plasma treatment can be performed to clean the substrate of any organic contamination, deoxidise it, texturize it to an arithmetic mean roughness (Ra) wanted between 0.2 and 0.8 and activate the surface before sintering. Additionally, drying the first sintering material and drying the second sintering material can be carried out at the same time.

Advantageously, the second sintering material serving to attach the components to the cap 15a, 15b or to the substrate 10 is identical to the first sintering material serving to form the annular beads 20a-20b. The manufacturing method is therefore particularly simple to implement. The first annular bead 20a is advantageously deposited at the same time as the first layer 21a or the second layer 22a. The second annular bead 20b is advantageously deposited at the same time as the third layer 22a or the fourth layer 22b.

In a step S4 represented by FIG. 4D, the first cap 15a is transferred to the first face 10a of the substrate 10 and the second cap 15b is transferred to the second face 10b of the substrate 10. The annular beads 20a-20b are disposed in contact with the substrate 10. Transfers are performed, for example, by means of “flip-chip” type equipment commonly employed in the microelectronics industry.

Preferably, the caps 15a-15b are positioned relative to the substrate 10 so that the annular beads 20a-20b face each other. This arrangement tends to reduce mechanical stresses.

Finally, step S5 in FIG. 4E consists in sintering the first sintering material to transform the annular beads 20a-20b into seals 16a-16b. The second sintering material is sintered simultaneously, forming the conductive seals 14 between the components 11a-11d and the substrate 10 and between the components 11a-11d and the caps 15a-15b. Sintering can be achieved in a partial vacuum or in air (no oxidation of the silver conductive tracks). The air can serve to eliminate (calcine) the remaining organic elements in the sintering paste(s).

Sintering can be made under pressure, by means of a heating press, according to predetermined temperature and pressure profiles, for example according to the method described in international application WO2022/200749A2. The heating press preferably comprises a heating arm and a support, on which the substrate-component-caps assembly is disposed. Preferably, the sintering step S5 comprises the following phases:
a first, so-called creep phase, during which the support and the arm are brought to a creep temperature of between 165° C. and 175° C. and are kept at this temperature for a period of time of between 30 s and 60 s, and during which a constant pressure of between 0.5 MPa and 1 MPa is applied for a period of time of between 15 s and 30 s after a rise of about 40 s;
a second, so-called sintering phase, of a period of time between 60 s and 400 s, during which the arm and support temperatures are kept constant between 205° C. and 255° C. and a pressure of between 10 MPa and 30 MPa is applied;
a third, so-called consolidation and cooling phase, during which the temperature decreases (back to room temperature, for example) while maintaining the pressure applied during the second phase.

The duration of the third phase is between 1 minute and 10 minutes, for example.

Alternatively, sintering is made without pressure, according to the method described in WO2017/046266A1, for example.

The manufacturing method described in connection with FIGS. 4A to 4E is simple to implement, because steps S2 and S3 are so-called “2D” assembly steps which can be made on panels, in parallel with each other (in other words simultaneously), unlike step S4 of transferring caps 15a-15b and sintering step S5 (“3D” assembly steps). Likewise, the steps of forming the conductive tracks 13 and the dielectric layers 18 on the substrate 10 and the caps 15a-15b can be performed in parallel.

1. An electronic power module comprising:
a substrate having a first face and a second face opposite to the first face;
a first electronic power component disposed on the first face of the substrate
a first cap disposed on the first face of the substrate and delimiting together with the substrate a first cavity in which the first electronic power component is housed;
a second electronic power component disposed on the second face of the substrate and
a second cap disposed on the second face of the substrate and delimiting together with the substrate a second cavity in which the second electronic power component is housed;
a first annular seal disposed between the substrate and the first cap, the first annular seal sealingly closing the first cavity
a second annular seal disposed between the substrate and the second cap the second annular seal sealingly closing the second cavity wherein the first and second annular seals are formed of a sintered material, and wherein the first and second cavities enclose a gas or a gas mixture.

2. The module according to claim 1, wherein:
the substrate is of metal;
the first electronic power component comprises a first terminal electrically connected to the substrate and a second terminal electrically connected to a conductive portion of the first cap
the second electronic power component comprises a first terminal electrically connected to the substrate and a second terminal electrically connected to a conductive portion of the second cap

3. The module according to claim 2, wherein each of the first and second electronic power components is electrically connected to the substrate via a conductive track and a conductive seal formed of the sintered material.

4. The module according to claim 2 wherein:
the first electronic power component is electrically connected to the conductive portion of the first cap via a conductive track and a conductive seal formed of the sintered material;
the second electronic power component is electrically connected to the conductive portion of the second cap via a conductive track and a conductive seal formed of the sintered material.

5. The module according to claim 1 wherein the first cap comprises:
a first substrate formed of a first electrically insulating ceramic material;
and
at least one first conductive element passing through the first substrate and electrically connected to the first electronic power component
wherein the second cap comprises:
a second substrate formed of a second electrically insulating ceramic material; and
at least one second conductive element passing through the second substrate and electrically connected to the second electronic power component

6. The module according to claim 5, wherein the first and second substrates are of aluminium nitride.

7. The module according to claim 1, wherein the first and second caps each comprise a metal layer and an electrically insulating layer disposed on an external face of the metal layer

8. An electromechanical actuator comprising at least one electronic power module according to claim 1,

9. The actuator according to claim 8, comprising a three-phase motor and a three-phase motor drive and supply circuit, the three-phase motor drive and supply circuit comprising a plurality of electronic power modules according to claim 1 for generating phase currents for the three-phase motor

10. The actuator according to claim 9, wherein each electronic power module is disposed facing a winding overhang of the three-phase motor

11. A method for manufacturing an electronic module comprising:
providing a substrate a first cap and a second cap
attaching a first electronic power component to the first cap
depositing a sintering material onto the first cap so as to form a first bead around the first electronic power component
attaching a second electronic power component to the second cap
depositing the sintering material onto the second cap so as to form a second bead around the second electronic power component
transferring the first cap to a first face of the substrate and the second cap to a second opposite face of the substrate, by disposing the first and second beads of sintering material in contact with the substrate; and
sintering the sintering material to form first and second annular seals the first annular seal sealingly closing a first cavity delimited by the first cap and the substrate and the second annular seal sealingly closing a second cavity delimited by the second cap and the substrate the first and second cavities enclosing a gas or gas mixture.

12. The method according to claim 11, wherein the substrate is of aluminium, the method further comprising, before the step of transferring the caps a step of forming silver-based conductive tracks on the first face and on the second face of the substrate the step of forming the silver-based conductive tracks comprising the following operations:
depositing by screen printing a paste comprising silver particles;
drying paste; and
annealing the paste at a temperature equal to or greater than 570° C.

13. The module according to claim 1, wherein the sintered material is silver.
